(19) United States
(12) Patent Application Publication
(10) Pub. No.: US 2026/0343934 A1
(43) Pub. Date: Oct. 29, 2026

(54) NANOSHEET DEVICE REVERSE INNER SPACER

(71) Applicant: International Business Machines Corporation, Armonk, NY (US)

(72) Inventors: Effendi Leobandung, Stormville, NY (US); Tze-chiang Chen, Yorktown Heights, NY (US); Julien Frougier, Albany, NY (US); Susan Ng Emans, Albany, NY (US); Rishikesh Krishnan, Cohoes, NY (US)

(21) Appl. No.: 19/188,663

(22) Filed: Apr. 24, 2025

(51) Int. Cl. H10D 30/00; H10D 30/01

(52) U.S. Cl. CPC H10D 30/508; H10D 30/0196

(57) ABSTRACT

A semiconductor device is provided having a decreased parasitic capacitance and hence an improved C_{eff}. The semiconductor device includes a nanosheet transistor having inner spacers located beneath each semiconductor channel material nanosheet, the inner spacers are shaped as an hourglass or as a semi-hourglass. Each inner spacer of the present application has a thickness next to the device channel that is thicker than a middle portion of the inner spacer that is located between two semiconductor channel material nanosheets.

### BACKGROUND

The present application relates to semiconductor technology, and more particularly to a semiconductor device including a nanosheet transistor having an improved capacitance value, C_{eff}, and a method of forming the same.

Nanosheet transistors are a type of field effect transistor (FET) that utilize multiple stacks of semiconductor channel material nanosheets, e.g., silicon nanosheets, surrounded by a gate structure. Such transistors facilitate reduction of current leakage and enhanced drive current. Nanosheet transistors offer several advantages over traditional finFETs including, for example, improved channel control and minimized short-channel effects, which allows for greater performance in a compact footprint. Nanosheet transistor fabrication includes several steps including, for example, epitaxial growth and channel release, making nanosheet transistors a significant advancement in semiconductor technology.

### SUMMARY

A semiconductor device is provided having a decreased parasitic capacitance and hence an improved transistor effective capacitance C_{eff}. The semiconductor device includes a nanosheet transistor having inner spacers located beneath each semiconductor channel material nanosheet, the inner spacers are shaped as an hourglass or as a semi-hourglass. Each inner spacer of the present application has a thickness next to the device channel that is thicker than a middle portion of the inner spacer that is located between two semiconductor channel material nanosheets.

In one embodiment of the present application, the semiconductor device includes a nanosheet transistor located on a semiconductor substrate, the nanosheet transistor including a vertical stack of spaced apart semiconductor channel material nanosheets, a gate structure wrapped around a middle portion of each semiconductor channel material nanosheet of the vertical stack of spaced apart semiconductor channel material nanosheets, an inner spacer located beneath each end portion of each semiconductor channel material nanosheet of the vertical stack of spaced apart semiconductor channel material nanosheets, and a source/drain region extending from a sidewall of each semiconductor channel material nanosheet of the vertical stack of spaced apart semiconductor channel material nanosheets, where the inner spacer has a first thickness along a topmost surface of the inner spacer that is greater than a second thickness as measured through a middle portion of the inner spacer.

In another embodiment of the present application, the semiconductor device includes a nanosheet transistor located on a semiconductor substrate, the nanosheet transistor including a vertical stack of spaced apart semiconductor channel material nanosheets, a gate structure wrapped around a middle portion of each semiconductor channel material nanosheet of the vertical stack of spaced apart semiconductor channel material nanosheets, an inner spacer having an hourglass shape located beneath each end portion of each semiconductor channel material nanosheet of the vertical stack of spaced apart semiconductor channel material nanosheets, and a source/drain region extending from a sidewall of each semiconductor channel material nanosheet of the vertical stack of spaced apart semiconductor channel material nanosheets.

In another embodiment of the present application, the semiconductor device includes a nanosheet transistor located on a semiconductor substrate, the nanosheet transistor including a vertical stack of spaced apart semiconductor channel material nanosheets, a gate structure wrapped around a middle portion of each semiconductor channel material nanosheet of the vertical stack of spaced apart semiconductor channel material nanosheets, an inner spacer having a semi-hourglass shape located beneath each end portion of each semiconductor channel material nanosheet of the vertical stack of spaced apart semiconductor channel material nanosheets, and a source/drain region extending from a sidewall of each semiconductor channel material nanosheet of the vertical stack of spaced apart semiconductor channel material nanosheets, where the inner spacer has a first sidewall with a curved surface that narrows from a top portion to a middle portion and then extends outward from the middle portion to a bottom portion, and a second sidewall, opposite the first sidewall, that is substantially vertical, and the source/drain region is in contact with the first sidewall.

A method of forming a semiconductor nanosheet device inner spacer in reverse, having the inner spacers of the present application as mentioned above is also provided in which sacrificial semiconductor material nanosheets are released earlier than in a traditional nanosheet transistor fabrication process, and thereafter a semi-conformal insulator layer is formed and will be subsequently processed into an inner spacer as mentioned above. The method of the present application does not include indenting the sacrificial semiconductor channel nanosheets and no full semiconductor channel material nanosheet release is required before the formation of the gate structure.

Notably, a method is provided that includes forming at least one nanosheet stack including alternating sacrificial semiconductor material nanosheets and semiconductor channel material nanosheets, where the at least one nanosheet stack is located beneath a sacrificial gate structure; removing each of the sacrificial semiconductor material nanosheets from the at least one nanosheet stack, where the removing of each of the sacrificial semiconductor material nanosheets forms a gap beneath each of the semiconductor channel material nanosheets; forming a precursor inner spacer within an end portion of the gap; forming a source/drain region from a sidewall of each of the semiconductor channel material nanosheets, wherein the forming of the source/drain region includes a cleaning process which converts at least a portion the precursor inner spacer into an inner spacer having a first thickness along a topmost surface of the inner spacer that is greater than a second thickness as measured through a middle portion of the inner spacer; removing the sacrificial gate structure; and forming a gate structure wrapping around each of the each of the semiconductor channel material nanosheets and in a remaining portion of each gap.

### BRIEF DESCRIPTION OF THE DRAWINGS

FIG. 1A is a cross-sectional view of an exemplary structure that can be employed in the present application, the exemplary structure including a semiconductor substrate, a material stack of alternating sacrificial semiconductor material layers and semiconductor channel material layers, and a hard mask layer.

FIG. 1B is a cross-sectional view of an alternative exemplary structure that can be employed in the present application, the alternative exemplary structure including a semiconductor substrate, a bottom dielectric isolation placeholder material layer, a material stack of alternating sacrificial semiconductor material layers and semiconductor channel material layers, and a hard mask layer.

FIGS. 2A-2C are various views (top-down, cross-sectional along cut X-X, and cross-sectional along cut Y-Y, respectively) of the exemplary structure of FIG. 1A after patterning the material stack to form at least one patterned material stack and forming a shallow trench isolation region in an upper portion of the semiconductor substrate.

FIGS. 3A-3B are various views (top-down, and cross-sectional along cut X-X, respectively) of the exemplary structure of FIGS. 2A-2C after forming a sacrificial gate structure straddling the at least one patterned material stack.

FIGS. 4A-4B are various views of the exemplary structure of FIGS. 3A-3B after forming a gate spacer along a sidewall of the sacrificial gate structure, and recessing the at least one patterned material stack utilizing the sacrificial gate structure and the gate spacer as an etch mask, while maintaining the at least one patterned material stack protected beneath the etch mask, the maintained portion of the at least one patterned material stack can be referred to as a nanosheet stack.

FIG. 4C is a cross-sectional view of the alternative exemplary structure through the processing steps illustrated in FIGS. 2A-2C, 3A-3B and 4A-4B in which, prior to spacer formation, the bottom dielectric isolation placeholder layer is removed and during gate spacer formation a bottom dielectric isolation layer is formed in the area previously including the bottom dielectric isolation placeholder layer.

FIGS. 5A-5B are various views of the exemplary structure of FIGS. 4A-4B after removing each sacrificial semiconductor material nanosheet of the nanosheet stack such that each semiconductor channel material nanosheet is suspended.

FIGS. 6A-6B are various views of the exemplary structure of FIGS. 5A-5B after forming a semi-conformal insulator layer.

FIGS. 7A-7B are various views of the exemplary structure of FIGS. 6A-6B after etching back the semi-conformal insulating layer to form a precursor inner spacer.

FIGS. 8A-8B are various views of the exemplary structure of FIGS. 7A-7B after curing an outer portion of the precursor inner spacer.

FIGS. 9A-9B are various views of the exemplary structure of FIGS. 8A-8B after forming a source/drain region on each side of the nanosheet stack and extending outward from each semiconductor channel material nanosheet present in the nanosheet stack.

FIGS. 10A-10B are various views of the exemplary structure of FIGS. 9A-9B after forming a dielectric liner.

FIGS. 11A-11B are various views of the exemplary structure of FIGS. 10A-10B after forming an interlayer dielectric layer.

FIG. 12 is a cross-sectional view of the exemplary structure of FIGS. 11A-11B after removing the sacrificial gate structure.

FIG. 13 is a cross-sectional view of the exemplary structure of FIG. 12 after removing the uncured portion of the precursor inner spacer.

FIGS. 14A-14B are cross-sectional views of various types of inner spacers that are present in inner spacer area, ISA, shown in FIG. 13.

FIG. 15 is a cross-sectional view of the exemplary structure of FIG. 13 after forming a gate structure including a gate dielectric layer and a gate electrode.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. As used herein, a "source/drain" region can be a source region or a drain region depending on subsequent wiring and application of voltages during operation of the transistor. In the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the sidewalls of the vertical stack of spaced apart semiconductor channel material nanosheets. The gate structure includes a gate dielectric and a gate electrode. The gate structure wraps around a middle portion of each of the spaced apart semiconductor channel material nanosheets. Nanosheet transistors provide considerable scaling with high drive current capability. Nanosheet transistors provide a larger drive current for a given footprint compared to finFET technology.

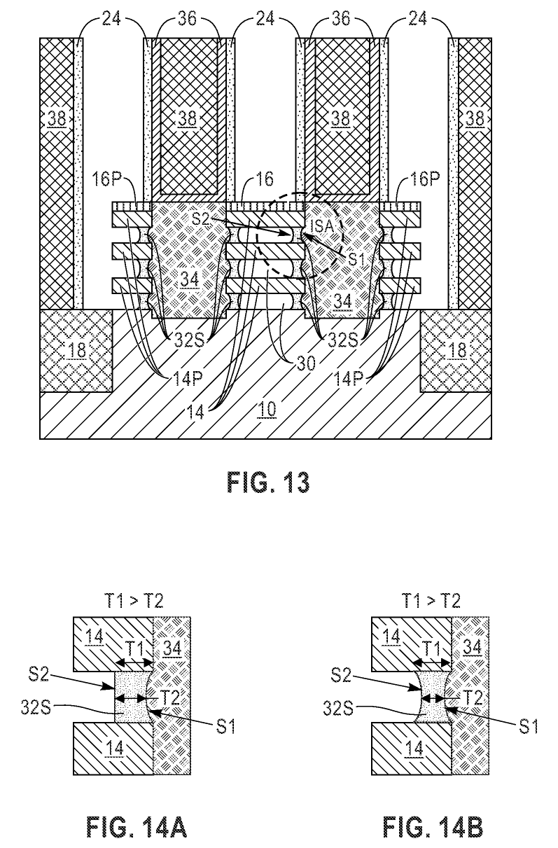

The nanosheet transistors of the present application include inner spacer 32S below, and at each end portion of, each semiconductor channel material nanosheet 14 that has a first thickness, T1, along a topmost surface of the inner spacer 32S that is greater than a second thickness, T2, as measured through a middle portion of the inner spacer 32S. FIG. 14A illustrates an embodiment in which the inner spacer 32S having such a thickness characteristic is a semi-hourglass inner spacer, while FIG. 14B illustrates an embodiment in which the inner spacer 32S having such a thickness characteristic is an hourglass inner spacer.

The hourglass inner spacer is characterized as having a first sidewall, S1, with a curved surface that narrows from a top portion to a middle portion and then extends outward from the middle portion to a bottom portion, and a second sidewall, S2, opposite S1, with a curved surface that narrows from the top portion to the middle portion and then extends outward from the middle portion to the bottom portion. The semi-hourglass inner spacer is characterized as having a first sidewall, S1 with a curved surface that narrows from a top portion to a middle portion and then extends outward from the middle portion to a bottom portion, and a second sidewall, S2, opposite S1, that substantially vertical (relative to the top and bottom surface of the inner spacer 32S). In both embodiments, the source/drain region 34 contacts the first sidewall, S1, while a portion of the gate structure contacts that second sidewall, S2.

The inner spacer 32S of the present application has better spacer retention than a conventical inner spacer which includes first and second sidewalls that are substantially vertical to the top and bottom surfaces of the inner spacer. The better spacer retention of inner spacer 32S of the present application leads to a semiconductor device having a lower C_{eff} than a semiconductor device including conventional inner spacers. The current inner spacer shape with T1>T2 is better than current conventional inner spacer where T1 is substantially less than T2, causing local thinning of the inner spacer near the device channel and degrading the device C_{eff}. Further, and in some embodiments, a higher stress from the source/drain region can be obtained. Because the inner spacer precursor is formed after removing the sacrificial semiconductor material nanosheets, it can be stressed more readily from process such as source drain epitaxy.

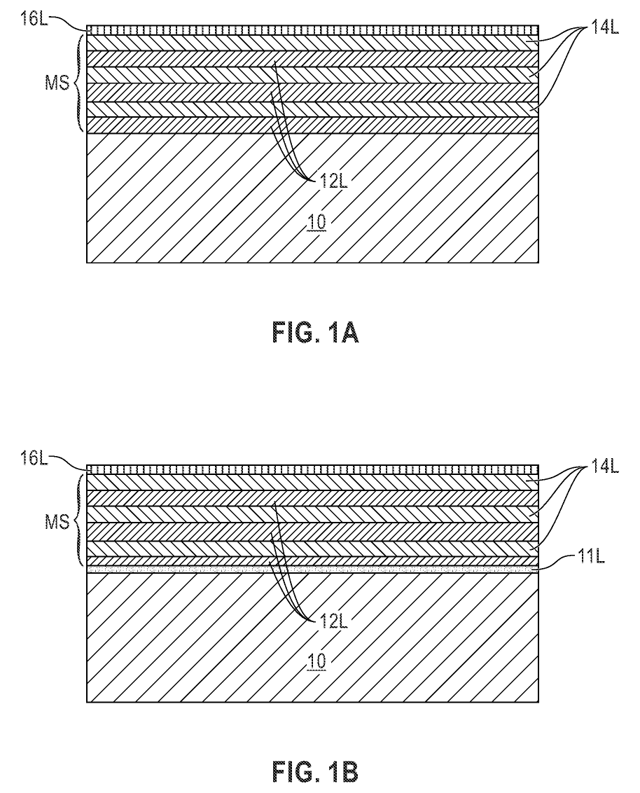

Referring first to FIG. 1A, there is illustrated an exemplary structure that can be employed in the present application. Notably, the exemplary structure illustrated in FIG. 1A includes semiconductor substrate 10, a material stack. MS, of alternating sacrificial semiconductor material layers 12L and semiconductor channel material layers 14L, and a hard mask layer 16L. As is illustrated in FIG. 1A, the material stack, MS, is located on top of the semiconductor substrate 10, and the hard mask layer 16L is located on top of the material stack, MS. Notably, a bottommost sacrificial semiconductor material layer of the material stack, MS, is formed on the semiconductor substrate 10, and the hard mask layer 16L is formed on a topmost semiconductor channel material layer of the material stack, MS.

The semiconductor substrate 10 is composed of a semiconductor material that has semiconducting properties (i.e., a semiconductor material). Illustrative examples of semiconductor materials that can be used as the semiconductor substrate 10 include, but are not limited to, silicon (Si), germanium (Ge), a silicon germanium (SiGe) alloy, silicon carbide (SiC), silicon germanium carbide (SiGeC), a III-V compound semiconductor or an II-VI compound semiconductor. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements. In some embodiments, the semiconductor substrate 10 is a bulk semiconductor substrate that is composed entirely of at least one of the semiconductor materials mentioned above. For example, a bulk silicon substrate can be used as the semiconductor substrate 10. In some embodiments, a semiconductor-on-insulator (SOI) substrate can be used as the semiconductor substrate 10. A SOI substrate includes an insulator layer such as, for example, silicon dioxide and/or boron nitride, sandwiched between a base semiconductor layer and a semiconductor device layer.

As mentioned above, the material stack, MS, includes alternating sacrificial semiconductor material layers 12L and semiconductor channel material layers 14L stacked one atop the other. In the present application, the material stack, MS, includes ‘n’ number of sacrificial semiconductor material layers 12L and ‘n’ number of semiconductor channel material layers 14L, wherein ‘n’ is an integer starting at one. By way of one example, and as is illustrated in the drawings, the material stack, MS, includes three sacrificial semiconductor material layers 12L and three semiconductor channel material layers 14L.

Each sacrificial semiconductor material layer 12L is composed of a first semiconductor material, while each semiconductor channel material layer 14L is composed of a second semiconductor material that is compositionally different from the first semiconductor material. In some embodiments, the second semiconductor material that provides each semiconductor channel material layer 14L is a semiconductor material that provides high channel mobility for n-type FET devices. In other embodiments, the second semiconductor material that provides each semiconductor channel material layer 14L is a semiconductor material that provides high channel mobility for p-type FET devices.

The first semiconductor material that provides each sacrificial semiconductor material layer 12L, and the second semiconductor material that provides each semiconductor channel material layer 14L can include one of the semiconductor materials mentioned above for the semiconductor substrate 10. In the present application, the first semiconductor material that provides each sacrificial semiconductor material layer 12L can be compositionally the same as, or compositionally different from, at least an uppermost semiconductor material portion/layer of the semiconductor substrate 10. The second semiconductor material that provides each semiconductor channel material layer 14L is typically compositionally the same as at least the uppermost semiconductor material portion/layer of the semiconductor substrate 10. In one example, the semiconductor substrate 10 is composed of silicon, the first semiconductor material that provides each sacrificial semiconductor material layer 12L is composed of a silicon germanium alloy, and the second semiconductor material that provides each semiconductor channel material layer 14L is composed of silicon. Other combinations of semiconductor materials are possible as long as the first semiconductor material that provides each sacrificial semiconductor material layer 12L is compositionally different from the second semiconductor material that provides each semiconductor channel material layer 14L.

The material stack, MS, including alternating sacrificial semiconductor material layers 12L and semiconductor channel material layers 14L can be formed utilizing one or more deposition processes including for example, chemical vapor deposition (CVD), plasma enhanced chemical vapor deposition (PECVD) or epitaxial growth. In one exemplary embodiment, the material stack, MS, is formed by epitaxial growing in an alternating manner sacrificial semiconductor material layer 12L and semiconductor channel material layer 14L. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450ºC to 900ºC. Although higher temperature typically results in faster deposition, the faster deposition may result in crystal defects and film cracking.

The hard mask layer 16L is composed of one or more hard mask materials. Illustrative examples of hard masks materials that can be used in providing the hard mask layer 16L include, but are not limited to, silicon dioxide, silicon nitride, silicon oxynitride and combinations thereof. The hard mask layer 16L can be formed by a deposition process including, but not limited to, CVD, PECVD, physical vapor deposition (PVD) or atomic layer deposition (ALD).

Reference is now made to FIG. 1B which illustrates an alternative exemplary structure that can be employed in the present application. The alternative exemplary structure illustrated in FIG. 1B is similar to the exemplary structure illustrated in FIG. 1B except that a bottom dielectric isolation placeholder material layer 11L is present between the material stack, MS, and the semiconductor substrate 10. The bottom dielectric isolation placeholder material layer 11L is composed of a third semiconductor material that is compositionally different from the first semiconductor material that provides the sacrificial semiconductor material layers 12L, the second semiconductor material that provides the semiconductor channel material layers 14L, and an uppermost semiconductor material/layer of the semiconductor substrate 10. In one example, the bottom dielectric isolation placeholder material layer 11L is composed of silicon germanium (i.e., SiGe) in which the SiGe has a germanium content of 50 atomic percent or greater, the sacrificial semiconductor material layers 12L are composed of SiGe but with a lower Ge content (e.g., from 20 atomic percent to 30 atomic percent), the semiconductor channels material layers 14L and the uppermost portion/layer of the semiconductor substrate 10 are composed of Si. The bottom dielectric isolation placeholder material layer 11L can be formed by a deposition process such as, for example, CVD, PECVD or epitaxial growth. It is noted that the alternative exemplary structure shown in FIG. 1B can be processed in the same manner as the exemplary structure shown in FIG. 1A.

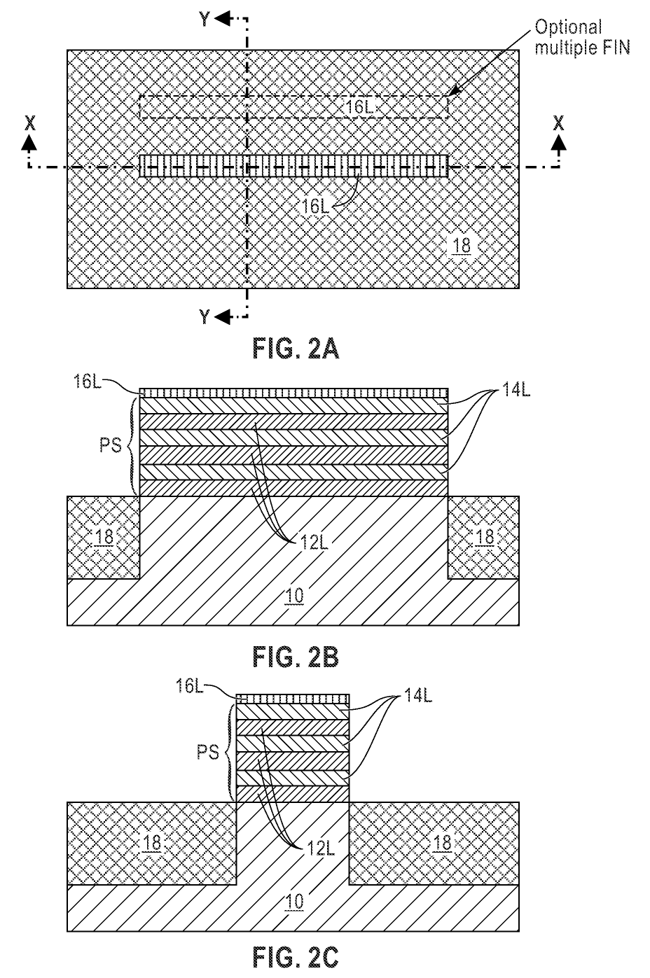

Referring now to FIGS. 2A-2C, there are illustrated the exemplary structure of FIG. 1A after patterning the material stack, MS, to form at least one patterned material stack, PS, and forming shallow trench isolation region 18 in an upper portion of the semiconductor substrate 10. It is noted that FIG. 2A represents a top-down view of the exemplary structure after forming the at least one patterned material stack, PS, and shallow trench isolation region 18. The top-down view as seen in FIG. 2Aincludes a X-X cut which runs in a lengthwise direction through one of the patterned material stacks, and a Y-Y which runs in a widthwise direction through a portion of the at least one patterned material stack, PS. FIG. 2B is a cross-sectional view along X-X, while FIG. 2C is a cross-sectional view along Y-Y.

The patterning of the material stack, MS, includes lithography and etching. Throughout the present application, lithography denotes a process in which a photoresist material is first formed on a layer or structure that needs to be patterned. The photoresist material can be formed by a deposition process including, for example, CVD, PECVD or spin-on coating. The as-deposited photoresist material is then subjected to a desired pattern of irradiation. The exposed photoresist material is then developed utilizing a resist developer to provide a patterned photoresist. The etch (often referred as a pattern transfer etch) used in the patterning process can include, for example, a dry etching process, a wet chemical etching process or a combination of dry etching and wet chemical etching. Dry etching can include reactive ion etching (RIE), ion beam etching (IBE) or plasma etching. Although a single patterned stack, PS, is described and illustrated, a plurality of patterned stacks (see, for example, FIG. 2A in which the doted area represents an area for forming another patterned material stack) can be formed. In the present application, the patterned photoresist can be removed any time after the pattern has been transferred into the hard mask layer 16L. The patterned photoresist can be removed utilizing any material removal process such as, for example, a resist stripping process (i.e., ashing), that is selective in removing the patterned photoresist from the exemplary structure.

In the present application, the pattern transfer etch etches entirely through the hard mask layer 16L and the material stack, MS, stopping on a surface of semiconductor substrate 10. A portion of the hard mask layer 16L and a portion of the material stack, MS, remain after the pattern transfer etch as is illustrated in FIGS. 2B-2C. The remaining portion of the hard mask layer 16L and the remaining portion of the material stack, MS, including a remaining portion of the sacrificial semiconductor material layers 12L and a remaining portion of the semiconductor channel material layers 14L constitute the patterned material stack, PS, illustrated in FIGS. 2B-2C.

Shallow trench isolation region 18 includes a trench dielectric material such as, for example, silicon dioxide. In some embodiments, a trench dielectric liner (not shown) can be present along a sidewall and a bottommost surface of the trench dielectric material. The trench dielectric liner is composed of a trench dielectric liner material such as, for example, silicon nitride. The shallow trench isolation region 18 can be formed utilizing any shallow trench isolation formation technique that is well known to those skilled in the art. For example, the shallow trench isolation region 18 can be formed by first forming a trench in the semiconductor substrate 10. The trench can be formed by lithography and etching. After forming the trench in the semiconductor substrate 10, a trench dielectric liner material is optionally formed along the sidewall and bottommost surface of the trench, and thereafter the trench dielectric material is formed in a remaining volume of the trench. A planarization process, such as, for example, chemical mechanical planarization (CMP) can then be performed, followed by an etch back process. In some embodiments, the shallow trench isolation region 18 can have a topmost surface that is substantially coplanar with a topmost surface of the semiconductor substrate 10. In other embodiments, the shallow trench isolation region 18 has a topmost surface that extends above or below the topmost surface of the semiconductor substrate 10.

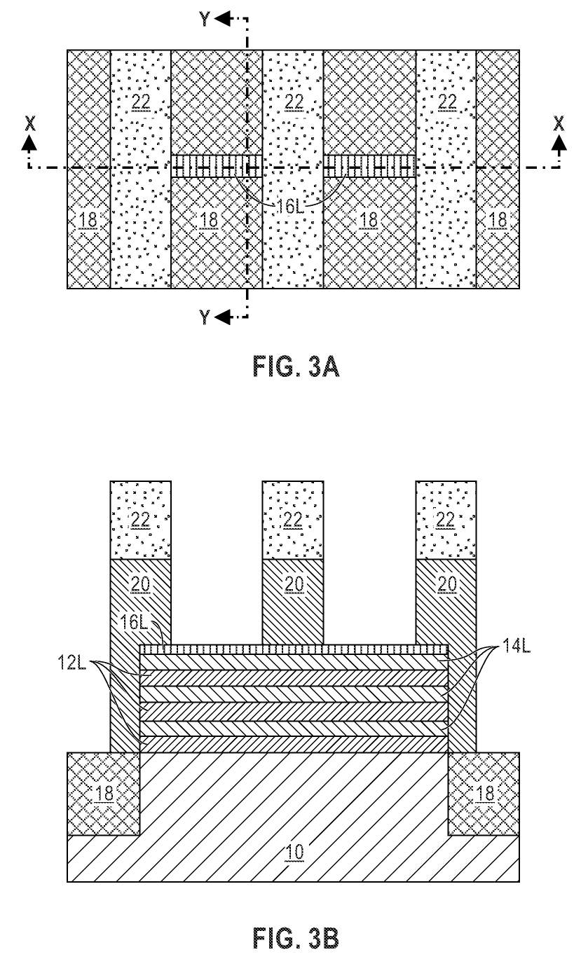

Referring now to FIGS. 3A-3B, there are illustrated the exemplary structure of FIGS. 2A-2C after forming a sacrificial gate structure 20 straddling the at least one patterned material stack, PS. Note that FIG. 3B is a cross-sectional along X-X. The number of sacrificial gate structures 20 that are formed can vary so long as at least one is formed. In the illustrated embodiment, three sacrificial gate structures 20 are shown by way of illustration. In the illustrated embodiment, the sacrificial gate structures 20 to the right and left of the middle sacrificial gate structure are used as bookends to protect the edge of the patterned material stack, PS, during, nanosheet transistor device fabrication. Notably, the sacrificial gate structures 20 to the right and left of the middle sacrificial gate structure staddle over only a portion of the patterned material stack, PS, and are present along an end wall of the patterned material stack, PS. These partial straddling sacrificial gate structures to the right and left of the middle sacrificial gate structure are not needed in all embodiments of the present application. In some embodiments, and as illustrated in FIGS. 3A-3B, a sacrificial gate cap 22 can be present on top of the sacrificial gate structure 20. In other embodiments, the sacrificial gate cap 22 can be omitted.

Each sacrificial gate structure 20 includes at least a sacrificial gate material. In some embodiments, the sacrificial gate structure 20 can also include a sacrificial gate dielectric material. In such embodiments, the sacrificial gate dielectric material would be located beneath the sacrificial gate material. The optional sacrificial gate dielectric material can be composed of a dielectric material such as, for example, silicon dioxide. The sacrificial gate material can be composed of, for example, polysilicon, amorphous silicon, amorphous silicon germanium or amorphous germanium. The sacrificial gate cap 22 is composed of any dielectric hard mask material such as, for example, silicon nitride, silicon oxide, and/or silicon oxynitride.

The sacrificial gate structure 20 and, if present, the sacrificial gate cap 22 can be formed by deposition of a blanket layer of at least the sacrificial gate material, followed by deposition of a blanket layer of the dielectric hard mask material. The blanket layer of at least the sacrificial gate material and the blanket layer of the dielectric hard mask material are then patterned (by lithography and etching) to form the sacrificial gate structure 20 and the sacrificial gate cap 22, respectively.

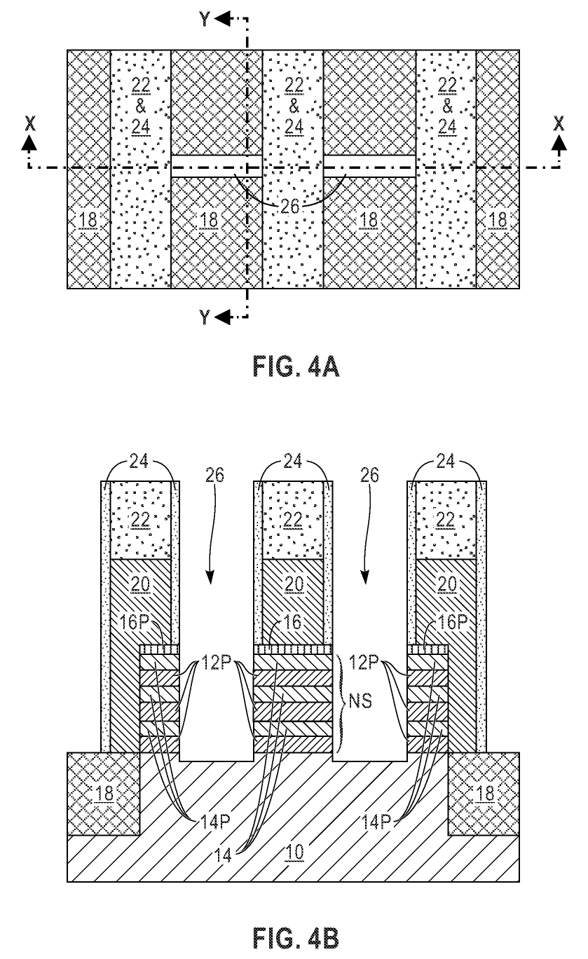

Referring now to FIGS. 4A-4B, there are illustrated the exemplary structure of FIGS. 3A-3B after forming gate spacer 24 along a sidewall of the sacrificial gate structure 20, and recessing the at least one patterned material stack, PS, utilizing the sacrificial gate structure 20 and the gate spacer 24 as an etch mask, while maintaining the at least one patterned material stack, PS, protected beneath the etch mask, the maintained portion of the at least one patterned material stack can be referred to as a nanosheet stack, NS. The nanosheet stack, NS, that is beneath the middle sacrificial gate structure includes alternating sacrificial semiconductor material nanosheets 12 and semiconductor channel material nanosheets 14, while the nanosheet stack that is located beneath the right or left sacrificial gate structure includes alternating reduced-width sacrificial semiconductor material nanosheets 12P and reduced-width semiconductor channel material nanosheets 14P.

The gate spacer 24 is composed of a spacer dielectric material including, but not limited to, silicon dioxide, silicon nitride (SiN), SiBCN, SiOCN or SiOC. The gate spacer 24 can be formed by deposition (e.g., CVD, PECVD, or ALD) of a spacer dielectric material, followed by a spacer etching process such as, for example, RIE.

The recessing of the at least one patterned material stack, PS, which is not protected by the etch mask includes an etching process such as, for example, RIE. The etch also removes portions of the hard mask layer 16L that are not protected by the etch mask; the remaining hard mask layer 16L to the right or left of the middle sacrificial gate structure can be referred to as a reduced-width hard mask nanosheet 16P, while the remaining hard mask layer under the middle sacrificial gate structure can be referred to a hard mask nanosheet 16. The recessing can also remove an uppermost portion of the semiconductor substrate 10 such that a sub-surface of the semiconductor substrate 10 is exposed in opening 26 created by the recessing. The term “sub-surface” as used throughout the present application denotes a surface of a layer/structure that is located between a topmost surface and a bottommost surface of the layer/structure.

Referring to FIG. 4C, there is illustrated the alternative exemplary structure of FIG. 1B after performing the processing steps mentioned above for forming the exemplary structures shown in FIGS. 2A-2B and 3A-3B, removing the bottom dielectric isolation placeholder layer 11 from beneath each patterned material stack, then forming the gate spacer 24 and thereafter performing the recessing mentioned above. It is noted that during gate spacer formation, the gate spacer dielectric forms in the area which previously included the bottom dielectric isolation placeholder layer 11 forming bottom dielectric isolation layer 13 as illustrated in FIG. 4C.

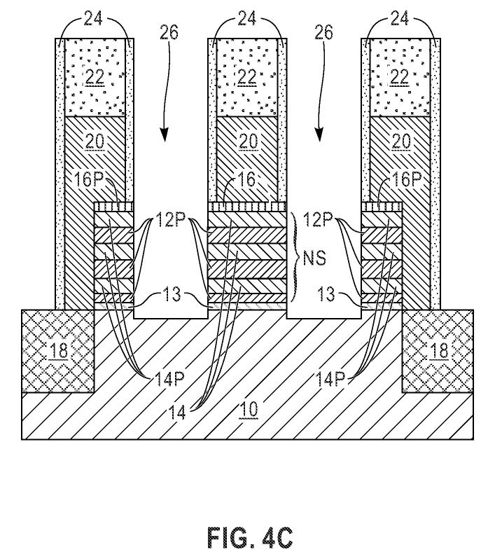

Referring now to FIGS. 5A-5B, there are illustrated the exemplary structure of FIGS. 4A-4B after removing each sacrificial semiconductor material nanosheet 12 of the nanosheet stack, NS, such each semiconductor channel material nanosheet 14 is suspended. Each semiconductor channel material nanosheet 14 that is suspended includes a first end portion, a middle portion, and a second end portion. At this point of the present application, the end portions of each semiconductor channel material nanosheet 14 are located beneath the gate spacer and the middle portion of each semiconductor channel material nanosheet 14 is located beneath the sacrificial gate structure 20. Each semiconductor channel material nanosheet 14 is spaced apart by a gap as shown in FIG. 5B. The end portion of the gap is an area in which the inner spacer of the present will be subsequently formed, while the middle portion of the gap is an area in which a portion of the gate structure will be subsequently formed.

Also, and in the illustrated embodiment, each reduced-width sacrificial semiconductor material nanosheet 12P of the nanosheet stacks, NS, to the right or left of the central nanosheet stack, NS, is removed such that each reduced-width semiconductor channel material nanosheet 14P is suspended; a gap is also present beneath each reduced-width semiconductor channel material nanosheet 14P. The removal of each sacrificial semiconductor material nanosheet 12 and reduced-width sacrificial semiconductor material nanosheet 12P occurs simultaneously utilizing an etch that is selective in removing each sacrificial semiconductor material nanosheet 12 and reduced-width sacrificial semiconductor material nanosheet 12P from the respective nanosheet stack, NS. This step of the present application releases each semiconductor channel material nanosheet 14 and each reduced-width semiconductor channel material nanosheet 14P from their respective nanosheet stack, NS.

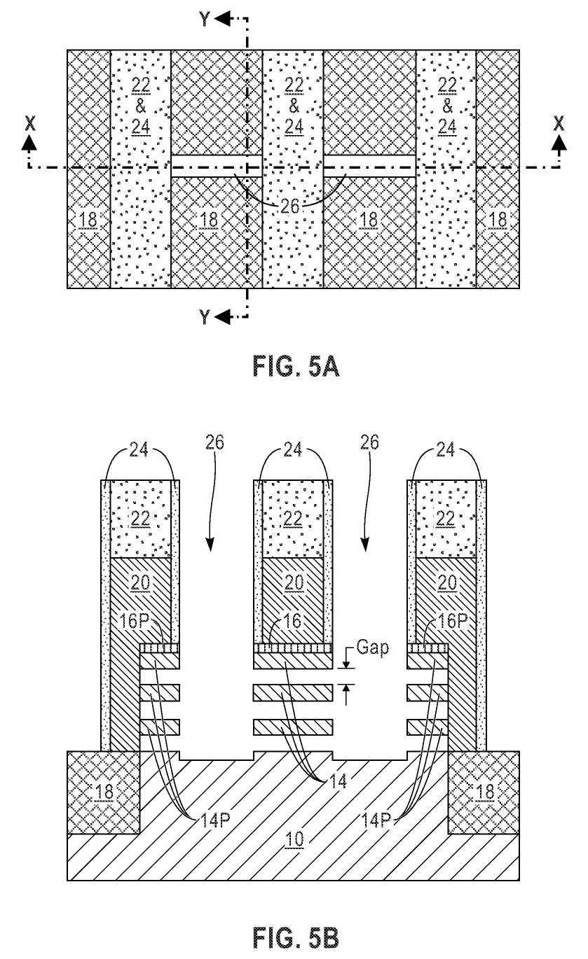

Referring now to FIGS. 6A-6B, there are illustrated the exemplary structure of FIGS. 5A-5B after forming a semi-conformal insulator layer 28L. The term “semi-conformal” denotes that the film is deposited such that it does not conformally fill a gap, such as in between the semiconductor channel material nanosheets 14. The semi-conformal insulator layer 28L is formed along the sidewall of the gate spacer 24, on top of each sacrificial gate cap 22 (or atop each sacrificial gate structure 20 if the sacrificial gate cap 22 is not present) and within opening 26. Within the opening 26, the semi-conformal insulator layer 28L partially fills in the gap that is located beneath each semiconductor channel material nanosheet 14 and each reduced-width semiconductor channel material nanosheet 14P. As is illustrated in FIG. 6B, void 29 remains in the gap that is located beneath each reduced-width semiconductor channel material nanosheet 14P, while void 30 remains in the gap that is located beneath each semiconductor channel material nanosheet 14. The formation of void 29 and void 30 are intentional and are used in the present application in forming the inner spacers of the present application. The semi-conformal insulator layer 28L is composed of a dielectric material such as, for example, a dielectric oxide, a dielectric nitride, a dielectric oxynitride or a dielectric material that includes at least atoms of O, N and C. In one example, the semi-conformal insulator layer 28L is composed silicon dioxide, silicon nitride, silicon oxynitride or silicon including at least atoms of O, N and C. The semi-conformal insulator layer 28L can be formed by a deposition process such as, for example, CVD, PECVD, or sputtering.

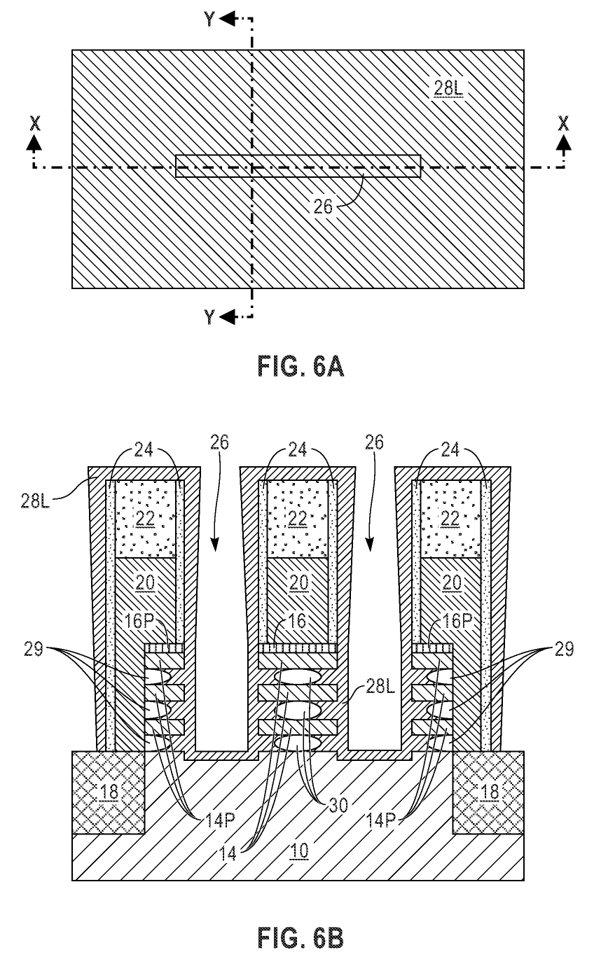

Referring now to FIGS. 7A-7B, there are illustrated the exemplary structure of FIGS. 6A-6B after etching back the semi-conformal insulating layer 28L to form a precursor inner spacer 28. The etch back process occurs in a device area or areas in which one of an n-type nanosheet transistor or a p-type nanosheet transistor is to be formed. The etch back process includes a dry process such as RIE or a chemical wet etch process using, for example, hydrofluoric acid (i.e., Hf). The precursor inner spacers 28 that are formed have an outermost sidewall that is vertically aligned to an outermost sidewall of gate spacer 24 and an outermost sidewall of each semiconductor channel material nanosheet 14 and each reduced-width semiconductor channel material nanosheet 14P from their respective nanosheet stack, NS.

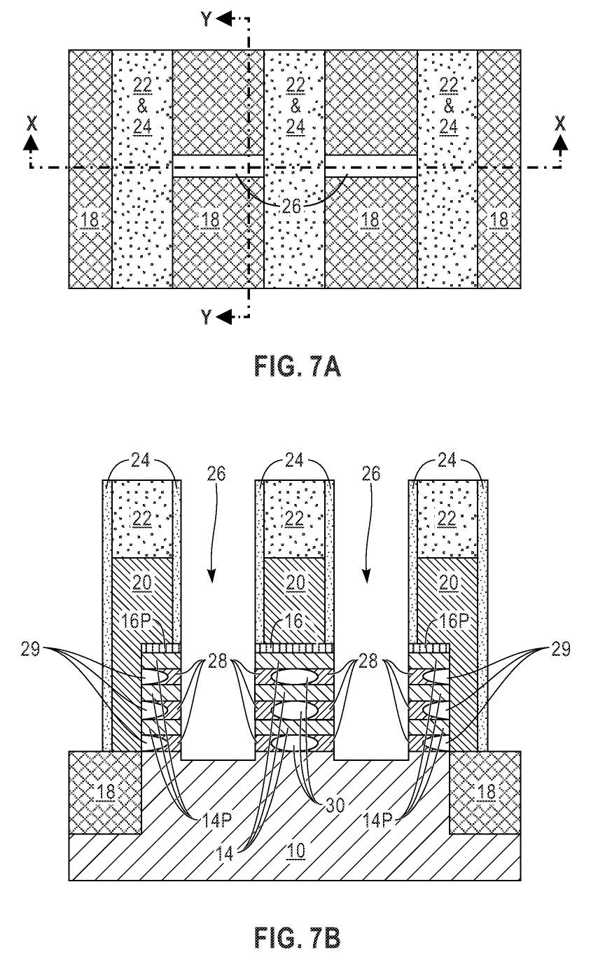

Referring now to FIGS. 8A-8B, there are illustrated the exemplary structure of FIGS. 7A-7B after curing an outer portion of the precursor inner spacer 28. The curing step is optional and is not needed in all embodiments of the present application. Curing may allow easier formation of the reverse inner spacer where the uncured inner spacer precursor can be removed much faster than cured inner spacer, hence allow more robust end inner spacer shape. The cured portion of the precursor inner spacer 28 can be referred to as cured precursor inner spacer 32. The cured precursor inner spacer 32 is composed of the same material as the precursor inner spacer 28 but has a hardness that is greater than the hardness of the precursor inner spacer 28. The increased hardness of the cured precursor inner spacer 32 is caused by chemical reaction to convert more of the deposit material into a harder material such as silicon dioxide. The increased hardness of the cured precursor inner spacer 32 provides a different etch rate for the cured precursor inner spacer 32 as compared to the precursor inner spacer 28. This different etch rate makes it easier to remove the precursor inner spacer 28 from the exemplary structure, relative to cured precursor inner spacer 32. The cured precursor inner spacers 32 that are formed have an outermost sidewall that is vertically aligned to an outermost sidewall of gate spacer 24 and an outermost sidewall of each semiconductor channel material nanosheet 14 and each reduced-width semiconductor channel material nanosheet 14P in their respective nanosheet stack, NS.

The curing can be performed at a temperature that can facilitate the hardness changed mentioned above. In one example, curing can be performed at a temperature from 300º C. to 500º.C. Curing is typically performed in an inert ambient such as, for example, helium and/or argon. Curing can also be achieved by shining UV light from the void 30 or void 29.

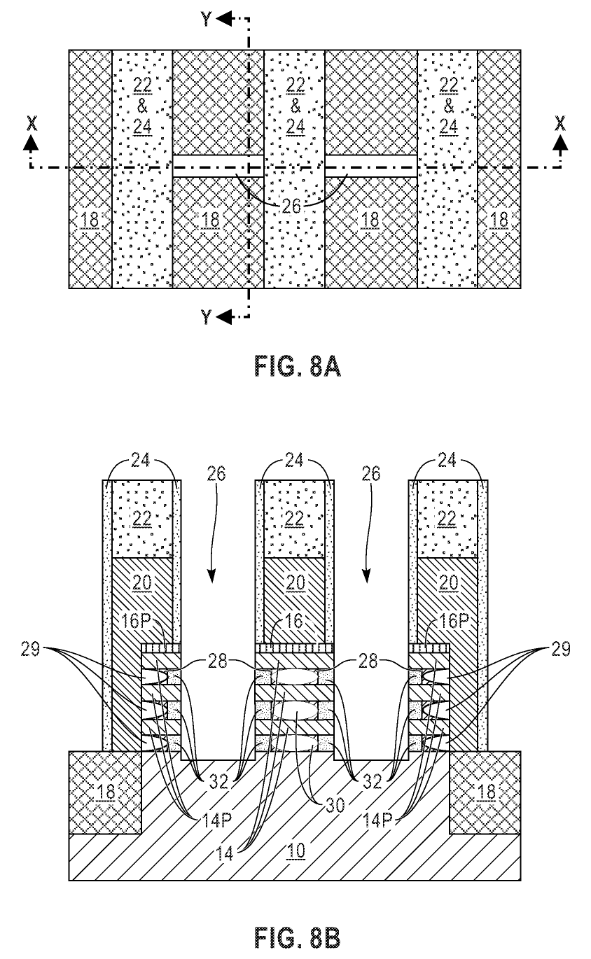

Referring now to FIGS. 9A-9B, there are illustrated the exemplary structure of FIGS. 8A-8B after forming a source/drain region 34 on each side of the nanosheet stack and extending outward from each semiconductor channel material nanosheet (e.g., semiconductor channel material nanosheets 14) present in the nanosheet stack. The source/drain region 34 can also be formed outward from each of the reduced-width semiconductor channel material nanosheets 14P, as is shown in FIG. 9B.

Each source/drain region 34 is composed of fourth semiconductor material and a dopant. The fourth semiconductor material that provides the source/drain region 34 is composed of one of the semiconductor materials mentioned above. The fourth semiconductor material that provides the source/drain region 34 can be compositionally the same as, or compositionally different from, the second semiconductor material that provides each of the semiconductor channel material layers 14L. The dopant can be either a p-type dopant or an n-type dopant. The term "p-type" refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. "N-type" refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the source/drain region 34 can have a dopant concentration of from 1x10²⁰ atoms/cm³ to 1x10²¹ atoms/cm³. The source/drain region 34 can be formed by epitaxial growth in which a dopant ion is present during the deposition of the fourth semiconductor material. Prior to the epitaxial growth, a cleaning process is performed. The cleaning process can include, for example, washing/rinsing in a hydrofluoric acid solution. The cleaning process is performed to remove any contaminants that can be present on surface in which the source/drain region 34 will be formed. In addition to removing contaminants, the cleaning process also indents the cured precursor inner spacer 32 as is shown in FIG. 9B. In embodiments in which curing is not performed, the cleaning process indents the precursor inner spacer 28. The cleaning process is required and is used to provide the hourglass or semi-hourglass inner spacers of the present application.

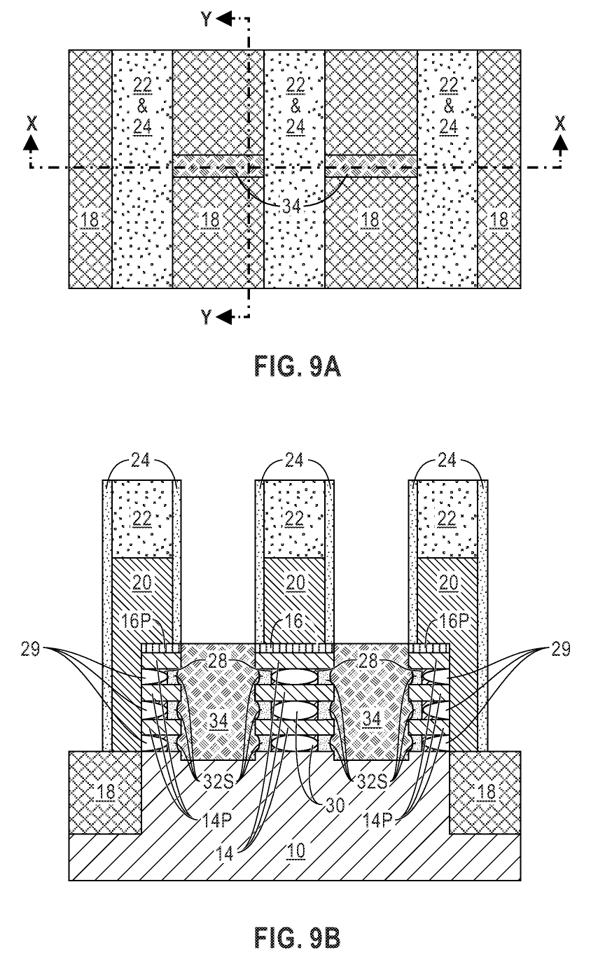

Referring now to FIGS. 10A-10B, there are illustrated the exemplary structure of FIGS. 9A-9B after forming a dielectric liner 36. Dielectric liner 36 is composed of a dielectric material such as, for example, silicon dioxide, silicon nitride and/or silicon oxynitride. As illustrated in FIG. 10B, dielectric liner 36 is formed on top of each source/drain region 34 and along a sidewall of gate spacer 24. The dielectric liner 36 can be a conformal liner. By “conformal” it is meant that the dielectric liner 36 has a measured thickness along the topmost surface of the source/drain region 34 that is substantially the same as a measured thickness along the sidewall of the gate spacer 24. At this point of the present application, the processing steps shown in FIGS. 7A-10B can be repeated in the device area(s) in which an opposite polarity type nanosheet transistor is to be formed.

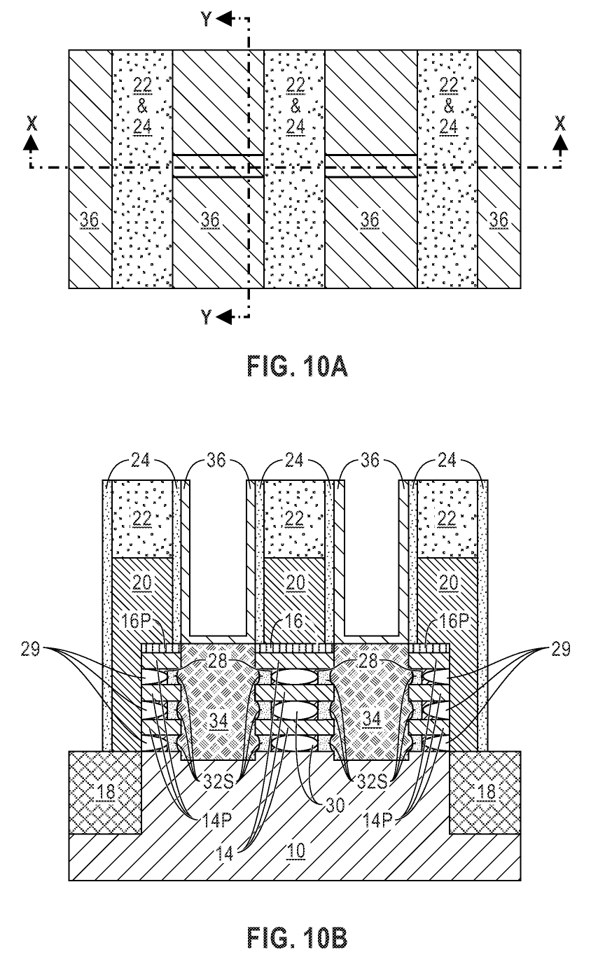

Referring now to FIGS. 11A-11B, there are illustrated the exemplary structure of FIGS. 10A-10B after forming an interlayer dielectric layer 38. The interlayer dielectric layer 38 is formed on the dielectric liner 36 as illustrated in FIG. 11B. The interlayer dielectric layer 38 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposited low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The interlayer dielectric layer 38 can be formed by a deposition process including, but not limited to, CVD, PECVD or spin-on coating. A planarization process such as, for example, CMP follows the deposition process. The planarization process can stop on a surface of the sacrificial gate cap 22 (if the same is present) or, when the sacrificial gate cap 22 is not present, the planarization process can stop on an upper portion of the sacrificial gate structure 20.

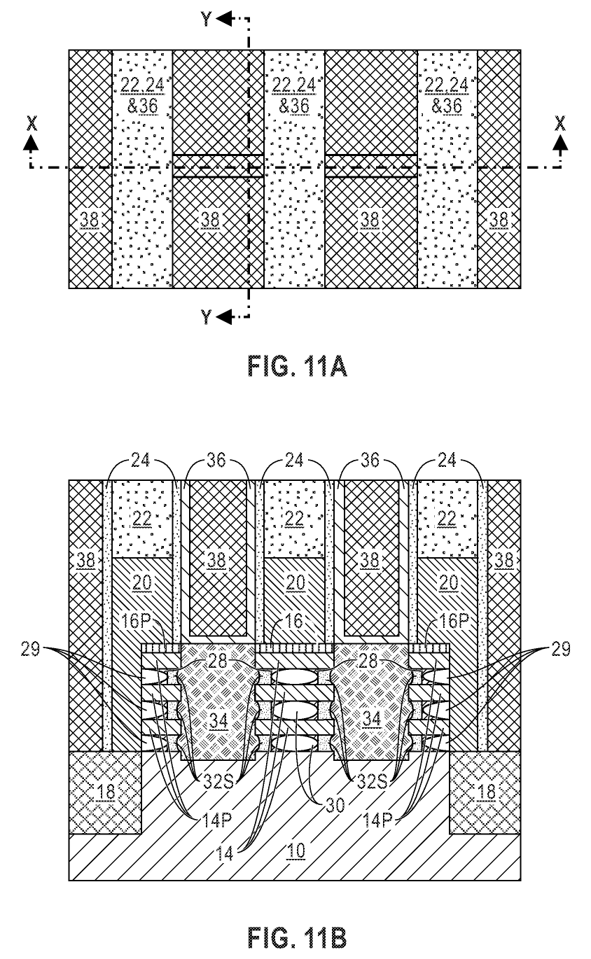

Referring now to FIG. 12, there are illustrated the exemplary structure of FIGS. 11A-11B after removing the sacrificial gate structure 20. It is noted that FIG. 12 is a cross-sectional along X-X. The removal of the sacrificial gate structure 20 can include first revealing the sacrificial gate structure 20 by removing the sacrificial gate cap 22. The removal of the sacrificial gate cap 22 includes an etch, e.g., RIE, that is selective in removing the sacrificial gate cap 22. After the sacrificial gate structure 20 is revealed, the sacrificial gate structure 20 can be removed utilizing an etch, e.g., RIE, or a combination of etches that is/are selective in removing the sacrificial gate structure 20. The removal of the sacrificial gate structure 20 forms a gate cavity 40. The gate cavity 40 is interconnected with the void 29 or void 30.

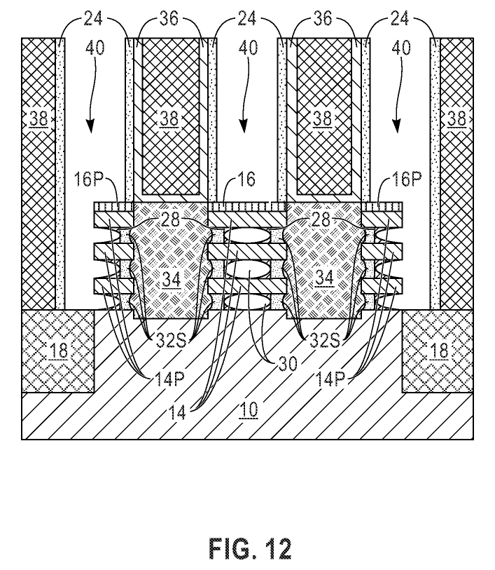

Referring now to FIG. 13, there is illustrated the exemplary structure of FIG. 12 after removing the uncured portion of the precursor inner spacer 28. The uncured portion of the precursor inner spacers 28 can be removed utilizing an etch process that is selective in removing the uncured portion of the precursor inner spacers 28 relative to the cured precursor inner spacers 32. In some embodiments, each cured precursor inner spacer 32 which is indented forms an inner spacer 32S in accordance with the present application. In accordance with another embodiment in which curing is not performed, a timed etch can be used to remove a portion of the precursor inner spacer 28, while maintaining another portion of the precursor inner spacer 28 beneath each semiconductor channel material nanosheet 14 and each reduced-width semiconductor channel material nanosheet 14P from the respective nanosheet stack, NS. The precursor inner spacer 28 that remains after this timed etch can be an inner spacer 32S in accordance with the present application. The inner spacers 32S that are formed in the present application are either hourglass shaped or semi-hourglass shaped. If no curing is done prior, the inner spacer 32S can still be formed accordingly without selective etching of cured and uncured materials, since the thickness of the inner spacer precursor is thinner on the region next to void 29 or void 30 versus next to the source/drain region 34.

By “hourglass shaped” it is meant that the inner spacer 32S has a first sidewall, S1, with a curved surface that narrows from a top portion to a middle portion and then extends outward from the middle portion to a bottom portion, and a second sidewall, S2, opposite the first sidewall, S1, with a curved surface that narrows from the top portion to the middle portion and then extends outward from the middle portion to the bottom portion. By “semi-hourglass shape” it is meant that the inner spacer 32S has a first sidewall, S1, with a curved surface that narrows from a top portion to a middle portion and then extends outward from the middle portion to a bottom portion, and a second sidewall, S2, opposite the first sidewall, S1, that is substantially vertical. In either embodiment, the first sidewall, S1, of the inner spacer 32S is nearer to the source/drain region 34 than the second sidewall, S2; the second sidewall, S2, will be nearer to the gate structure than the first sidewall, S1. In both embodiments “hourglass” and “semi-hourglass”, the source/drain region 34 contacts the first sidewall, S1. Because of the curved nature of the inner spacers 32S, the source/drain region 34 extends into a gap that is located adjacent to the first sidewall, S1, of the inner spacer 32S and beneath each semiconductor channel material nanosheet 14. This aspect of the present application can be seen by referring to FIGS. 13, 14A and 14B. Notably, FIGS. 14A and 14B illustrate various types of inner spacers 32S that are present in inner spacer area, ISA, shown in FIG. 13. The inner spacer area is the area beneath an end portion of each semiconductor channel material nanosheet 14 and each reduced-width semiconductor channel material nanosheet 14P of a respective nanosheet stack, NS, in which inner spacers 32S are present. FIG. 14A shows inner spacer 32S having a semi-hourglass shape as defined above, while FIG. 14B shows inner spacer 32S having an hourglass shape as defined above.

The inner spacer 32S of semi-hourglass shape as illustrated in FIG. 14A and the inner spacer 32S of hourglass shape as illustrated in FIG. 14B can be generically defined as an inner spacer having a first thickness, T1, measured along a topmost surface of inner spacer 32S that is greater than a second thickness, T2, as measured through a middle second of inner spacer 32S. Although not shown in either FIGS. 14A or 14B, the thickness along a bottom surface of the inner spacer 32S would be substantially equal to T1.

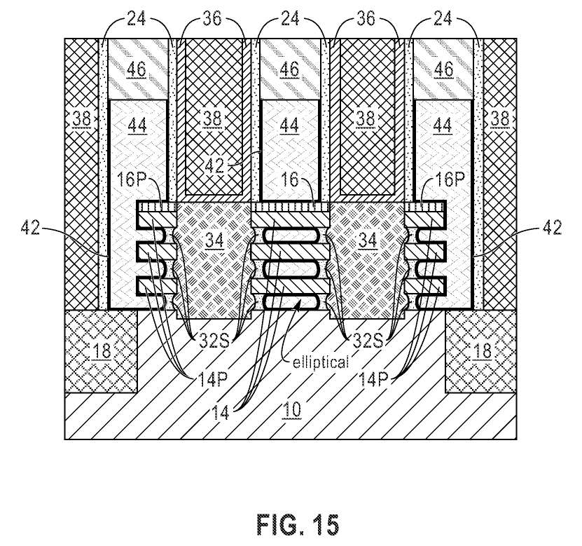

Referring now to FIG. 15, there is illustrated the exemplary structure of FIG. 13 after forming a gate structure including gate dielectric layer 42 and gate electrode 44. Beneath each semiconductor channel material nanosheet 14 the gate structure is elliptical in shape. In some embodiments and as illustrated in FIG. 15, gate cap 46 can be formed on top of the gate structure. In other embodiments, gate cap 46 can be omitted. The gate structure is formed in each gate cavity 40. Notably, the gate structure wraps around a physically exposed central portion of each of the semiconductor channel material nanosheets 14. A gate structure can also be formed that wraps around a physically exposed portion and one of the end portions each of the reduced-width semiconductor channel material nanosheets 14P. The gate dielectric layer 42 directly contacts a physically exposed surface(s) of the semiconductor channel region, and gate electrode 44 is formed on the gate dielectric layer 42. The gate dielectric layer 42 is composed of a gate dielectric material having a dielectric constant of 4.0 or greater. Illustrative examples of gate dielectric materials that can be employed as the gate dielectric layer 42 include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode 44 can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure can be formed by deposition of the gate dielectric material and then the gate electrode material, followed by planarization (e.g., CMP).

A recessed etch can be performed to reduce the height of the gate structure, and thereafter gate cap 46 is formed on top of the gate structure. The gate cap 46 can be composed of any gate cap material including, for example, silicon dioxide, silicon nitride, silicon oxynitride, a metal-containing cap or any combination thereof. The gate cap 46 can be formed by deposition of at least one gate cap material, followed by a planarization process (e.g., CMP).

It is noted that in embodiments in which a bottom dielectric isolation layer 13 is present, the gate structure would be spaced apart from the semiconductor substrate 10 by the bottom dielectric isolation layer 13. The presence of the bottom dielectric isolation layer 13 prevents unwanted parasitic capacitance to be introduced into the semiconductor substrate 10.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a nanosheet transistor located on a semiconductor substrate, the nanosheet transistor comprising a vertical stack of spaced apart semiconductor channel material nanosheets, a gate structure wrapped around a middle portion of each semiconductor channel material nanosheet of the vertical stack of spaced apart semiconductor channel material nanosheets, an inner spacer located beneath each end portion of each semiconductor channel material nanosheet of the vertical stack of spaced apart semiconductor channel material nanosheets, and a source/drain region extending from a sidewall of each semiconductor channel material nanosheet of the vertical stack of spaced apart semiconductor channel material nanosheets, wherein the inner spacer has a first thickness along a topmost surface of the inner spacer that is greater than a second thickness as measured through a middle portion of the inner spacer.

2. The semiconductor device of claim 1, wherein the gate structure is spaced apart from the semiconductor substrate by a bottom dielectric isolation layer.

3. The semiconductor device of claim 1, wherein the inner spacer has a first sidewall with a curved surface that narrows from a top portion to a middle portion and then extends outward from the middle portion to a bottom portion, and a second sidewall, opposite the first sidewall, with a curved surface that narrows from the top portion to the middle portion and then extends outward from the middle portion to the bottom portion.

4. The semiconductor device of claim 3, wherein the source/drain region is in contact with the first sidewall, and a portion of the gate structure is in contact with the second sidewall.

5. The semiconductor device of claim 1, wherein the inner spacer has a first sidewall with a curved surface that narrows from a top portion to a middle portion and then extends outward from the middle portion to a bottom portion, and a second sidewall, opposite the first sidewall, that is substantially vertical.

6. The semiconductor device of claim 5, wherein the source/drain region is in contact with the first sidewall, and a portion of the gate structure is in contact with the second sidewall.

7. The semiconductor device of claim 1, wherein the gate structure that located is beneath each semiconductor channel material nanosheet of the vertical stack of spaced apart semiconductor channel material nanosheets is elliptical in shape.

8. The semiconductor device of claim 1, wherein the source/drain region extends into a gap located beneath each semiconductor channel material nanosheet of the vertical stack of spaced apart semiconductor channel material nanosheets.

9. A semiconductor device comprising:
a nanosheet transistor located on a semiconductor substrate, the nanosheet transistor comprising a vertical stack of spaced apart semiconductor channel material nanosheets, a gate structure wrapped around a middle portion of each semiconductor channel material nanosheet of the vertical stack of spaced apart semiconductor channel material nanosheets, an inner spacer having an hourglass shape located beneath each end portion of each semiconductor channel material nanosheet of the vertical stack of spaced apart semiconductor channel material nanosheets, and a source/drain region extending from a sidewall of each semiconductor channel material nanosheet of the vertical stack of spaced apart semiconductor channel material nanosheets.

10. The semiconductor device of claim 9, wherein the gate structure is spaced apart from the semiconductor substrate by a bottom dielectric isolation layer.

11. The semiconductor device of claim 9, wherein the gate structure that is located beneath each semiconductor channel material nanosheet of the vertical stack of spaced apart semiconductor channel material nanosheets is elliptical in shape.

12. The semiconductor device of claim 9, wherein the source/drain region extends into a gap located beneath each semiconductor channel material nanosheet of the vertical stack of spaced apart semiconductor channel material nanosheets.

13. A semiconductor device comprising:
a nanosheet transistor located on a semiconductor substrate, the nanosheet transistor comprising a vertical stack of spaced apart semiconductor channel material nanosheets, a gate structure wrapped around a middle portion of each semiconductor channel material nanosheet of the vertical stack of spaced apart semiconductor channel material nanosheets, an inner spacer having a semi-hourglass shape located beneath each end portion of each semiconductor channel material nanosheet of the vertical stack of spaced apart semiconductor channel material nanosheets, and a source/drain region extending from a sidewall of each semiconductor channel material nanosheet of the vertical stack of spaced apart semiconductor channel material nanosheets, where the inner spacer has a first sidewall with a curved surface that narrows from a top portion to a middle portion and then extends outward from the middle portion to a bottom portion, and a second sidewall, opposite the first sidewall, that is substantially vertical, and the source/drain region is in contact with the first sidewall.

14. The semiconductor device of claim 13, wherein the gate structure is spaced apart from the semiconductor substrate by a bottom dielectric isolation layer.

15. The semiconductor device of claim 13, wherein the gate structure that is located beneath each semiconductor channel material nanosheet of the vertical stack of spaced apart semiconductor channel material nanosheets is elliptical in shape in shape.

16. The semiconductor device of claim 13, wherein the source/drain region extends into a gap located beneath each semiconductor channel material nanosheet of the vertical stack of spaced apart semiconductor channel material nanosheets.

17. The semiconductor device of claim 13, wherein the second sidewall is in contact with the gate structure.

18. A method of forming a semiconductor device, the method comprising:
forming at least one nanosheet stack comprising alternating sacrificial semiconductor material nanosheets and semiconductor channel material nanosheets, wherein the at least one nanosheet stack is located beneath a sacrificial gate structure;
removing each of the sacrificial semiconductor material nanosheets from the at least one nanosheet stack, wherein the removing of each of the sacrificial semiconductor material nanosheets forms a gap beneath each of the semiconductor channel material nanosheets;
forming a precursor inner spacer within an end portion of the gap;
forming a source/drain region from a sidewall of each of the semiconductor channel material nanosheets, wherein the forming of the source/drain region comprises a cleaning process which converts at least a portion the precursor inner spacer into an inner spacer having a first thickness along a topmost surface of the inner spacer that is greater than a second thickness as measured through a middle portion of the inner spacer;
removing the sacrificial gate structure; and
forming a gate structure wrapping around each of the each of the semiconductor channel material nanosheets and in a remaining portion of each gap.

19. The method of claim 18, wherein the forming of the precursor inner spacer comprising forming a semi-conformal insulator layer and performing an etch back process.

20. The method of claim 19, further comprising curing a portion of the precursor inner spacer to provide a cured precursor inner spacer having a hardness that is greater than a hardness of the precursor inner spacer.

21. The method of claim 18, further comprising removing a remaining portion of the precursor inner spacer, wherein the removing is performed after removing the sacrificial gate structure, and prior to the forming of the gate structure.

22. The method of claim 18, wherein the inner spacer has a first sidewall with a curved surface that narrows from a top portion to a middle portion and then extends outward from the middle portion to a bottom portion, and a second sidewall, opposite the first sidewall, with a curved surface that narrows from the top portion to the middle portion and then extends outward from the middle portion to the bottom portion.

23. The method of claim 18, wherein the inner spacer has a first sidewall with a curved surface that narrows from a top portion to a middle portion and then extends outward from the middle portion to a bottom portion, and a second sidewall, opposite the first sidewall, that is substantially vertical, and the first sidewall of the inner spacer is nearer to the source/drain region than the second sidewall.
